(19) United States
(12) Patent Application Publication
(10) Pub. No.: US 2008/0102557 A1
(43) Pub. Date: May 1, 2008

(54) Method of forming an isolation layer and method of manufacturing an image device using the same

(76) Inventors: Dae-Woong Kim, Seoul (KR); Mi-Young Lee, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/976,660

(22) Filed: Oct. 26, 2007

(30) Foreign Application Priority Data
Oct. 27, 2006 (KR) 2006-105097

(51) Int. Cl. H01L 31/18; H01L 21/762

(52) U.S. Cl. 438/73; 438/433; 257/E21.546

(57) ABSTRACT

A method of forming an isolation layer includes forming mask pattern structure on a substrate to partially expose the substrate, etching the substrate using the mask pattern as an etching mask to form a trench, forming an impurity diffusion region at an inner face of the trench, and filling the trench with the isolation layer. A method of manufacturing an image device includes the method of forming an isolation layer, and at least additionally forming unit pixels including a photo diode and transistors on an active region defined by the isolation layer.

### BACKGROUND OF THE INVENTION

1. Field of the Invention

Example embodiments of the present invention relate to a method of forming an isolation layer and a method of manufacturing an image device using the same.

2. Description of the Related Art

Generally, an image device may correspond to a semiconductor module for converting an optical image into an electrical signal. The image device may be used for storing and transmitting an image signal to a display device for displaying the image signal. The image device may be classified as a charge coupled device (CCD) image device or a complementary metal oxide semiconductor (CMOS) image device.

The CCD image device may include a plurality of MOS capacitors that may be operated by moving charges generated by light. In contrast, the CMOS image device may be driven by a plurality of unit pixels and a CMOS circuit for controlling an output signal of the unit pixels.

The CCD image device may have a complicated driving operation, a high power consumption and a complicated fabrication process. Further, since integrating a signal processing unit in a CCD chip may be difficult, forming the CCD image device as a single chip may also be difficult. In contrast, the CMOS image device may be formed by a general CMOS technology so is readily fabricable.

The CMOS image device may include an active pixel region for photographing an image, and a CMOS logic region for controlling an output signal from the active pixel region. Further, the active pixel region may include a photo diode and a MOS transistor. The CMOS logic region may include a plurality of CMOS transistors.

The active pixel region may be defined by an isolation pattern. According to a conventional method, the isolation pattern may be formed by a local oxidation of silicon (LOCOS) process. Recently, the isolation pattern may be formed by a trench isolation (TI) process.

Further, as the CMOS image device has been highly integrated, the isolation pattern may be formed by a deep trench isolation (DTI) process using a deeper trench to reduce cross talk.

However, when the isolation pattern having a DTI structure is used, an electron on the isolation pattern may infiltrate into the photo diode. The electron in the photo diode may cause a white spot or a dark level.

Moreover, as trenches become deeper, it becomes more difficult to completely fill the trench with isolation material. Consequently, a seam or a void in the isolation pattern may result so that the image device may suffer from deteriorated characteristics.

### SUMMARY OF THE INVENTION

Embodiments of the present invention are therefore directed to a method of forming an isolation layer that substantially overcomes one or more of the disadvantages of the related art.

It is therefore a feature of an embodiment of the present invention to provide a method of forming an isolation layer that is less susceptible to the generation of a seam or a void in an isolation pattern.

It is therefore a feature of an embodiment of the present invention to provide a method of forming an isolation layer that prevents or reduces the likelihood that an electron would infiltrate into an active region.

At least one of the above and other features and advantages of embodiments may be realized by providing a method of forming an isolation layer. Such a method may include: forming nitride mask pattern structure on a substrate to partially expose the substrate; etching the substrate using the mask pattern as an etching mask to form a trench; forming an impurity diffusion region at an inner face of the trench; and filling the trench with the isolation layer.

At least one of the above and other features and advantages of embodiments may be realized by providing a method of a method of manufacturing an image device. Such a method may include the method (noted above) of forming an isolation layer, and at least additionally forming unit pixels including a photo diode and transistors on an active region defined by the isolation layer.

### BRIEF DESCRIPTION OF THE DRAWINGS

The above and other features and advantages of the present invention will become readily apparent by reference to the following detailed description when considered in conjunction with the accompanying drawings, wherein:

FIGS. 1 to 9 illustrate cross-sectional views of stages in a method of forming an isolation layer in accordance with an example embodiment of the present invention; and

FIGS. 10 to 12 illustrate cross-sectional views of stages in a method of manufacturing an image device using the method depicted via FIGS. 1 to 9 in accordance with another example embodiment of the present invention.

### DETAILED DESCRIPTION OF EXAMPLE EMBODIMENTS

Korean Patent Application No. 10-2006-0105097 filed on Oct. 27, 2006, in the Korean Intellectual Property Office and entitled “Method of Forming an Isolation Layer and Method of Manufacturing an Image Device Using the Same,” is incorporated by reference herein in its entirety.

The present invention will now be described more fully hereinafter with reference to the accompanying drawings, in which example embodiments of the present invention are illustrated. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art.

In the figures, the dimensions of layers and regions may be exaggerated for clarity of illustration. It will also be understood that when a layer or element is referred to as being “on,” “connected to” or “coupled to” another layer or substrate, it can be directly on, connected to or coupled to the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening elements or layers may be present. In contrast, when an element is referred to as being “directly on,” “directly connected to” or “directly coupled to” another element or layer, there are no intervening elements or layers present. Like numbers refer to like elements throughout.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

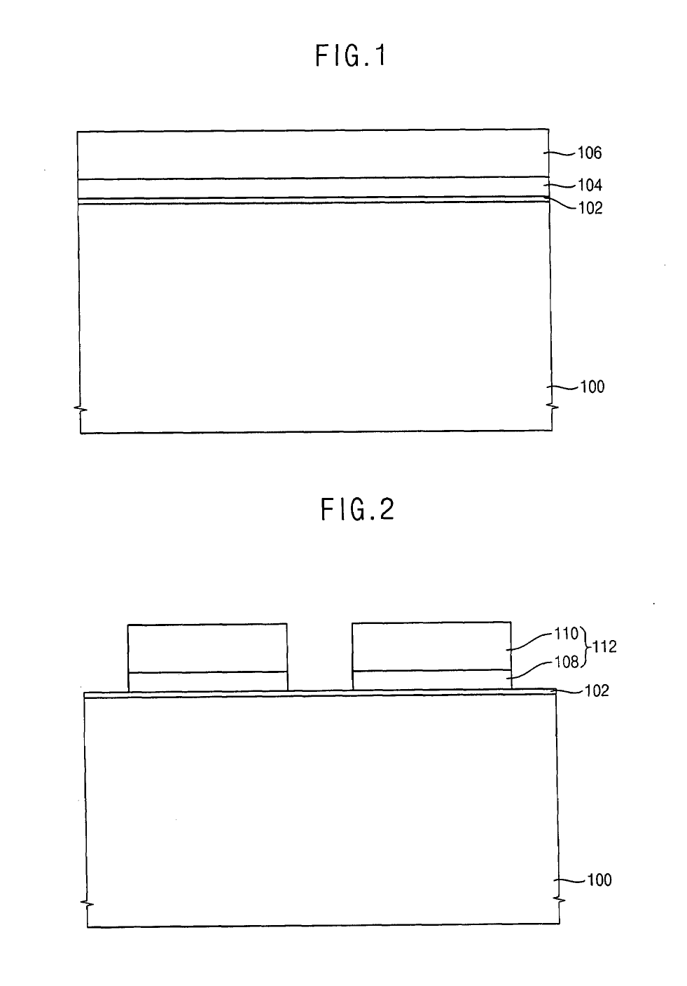

FIGS. 1 to 9 illustrate cross-sectional views of stages in a method of forming an isolation layer in accordance with an example embodiment of the present invention.

Referring to FIG. 1, a pad oxide layer 102, a first mask layer 104 and a second mask layer 106 may be sequentially formed on a semiconductor substrate 100, e.g., a silicon wafer.

The pad oxide layer 102 may reduce stresses between the semiconductor substrate 100 and nitride layer formed later. In this example embodiment, the pad oxide layer 102 may be thin, i.e., may be of a relatively smaller thickness, and may be formed by a thermal oxidation process, a chemical vapor deposition (CVD) process, etc.

The first mask layer 104 may be then formed on the pad oxide layer 102. In this example embodiment, the first mask layer 104 may include nitride. Particularly, the first mask layer 104 may include a silicon nitride layer. Further, the first mask layer 104 may have a thickness of about 800 Å to about 1,200 Å.

The second mask layer 106 may be then formed on the first mask layer 104. In this example embodiment, the second mask layer 106 may include a material having an etching selectivity with respect to an etchant for etching the first mask layer 104. For example, when the first mask layer 104 includes nitride, the second mask layer 106 may include oxide. More particularly as to this example, the second mask layer 106 may include a silicon oxide layer. Further, the second mask layer 106 may have a thickness of about 10,000 Å to about 14,000 Å.

Referring to FIG. 2, a photoresist pattern (not shown) may be formed on the second mask layer 106 to partially expose the second mask layer 106.

Here, portions of the second mask layer 106 exposed through the photoresist pattern may correspond to a region where an isolation pattern is formed. Other portions of the second mask layer 106 masked with the photoresist pattern may correspond to an active region defined by the isolation pattern.

Although not illustrated in drawings, before forming the photoresist pattern, an amorphous carbon layer (not shown) and an anti-reflective organic layer (not shown) may be sequentially formed on the second mask layer 106. The amorphous carbon layer and the anti-reflective organic layer may reduce (if not prevent) a failure of a side profile of the photoresist pattern due to a diffused reflection that is generated in a following photolithography process. In this example embodiment, the anti-reflective organic layer may include a silicon oxynitride layer. Further, the anti-reflective organic layer may be removed with the photoresist pattern.

The second mask layer 106 and the first mask layer 104 may then be etched using the photoresist pattern as an etching mask to form a mask pattern structure 112, e.g., nitride mask pattern structure on the pad oxide layer 102. The structure 112 may include a first mask pattern 108 on the pad oxide layer 102 and a sequentially stacked second mask pattern 110 on the first mask pattern 108. For example, a two-step process may be used to form the mask pattern structure 112. As a first step, portions of the second mask layer 106 may be removed (to form the second mask pattern 110) using an etchant having a significantly higher selectivity for the oxide material of the second mask layer 106 than for the nitride material of the first mask layer 104. As a second step, portions of the first mask layer 104 may be removed (to form the first mask pattern 108) using an etchant having a significantly higher selectivity for the nitride material of the first mask layer 104 than for the oxide material of the second mask pattern 110.

After forming the mask pattern structure 112, the photoresist pattern may be then removed by, e.g., an ashing process and/or a stripping process.

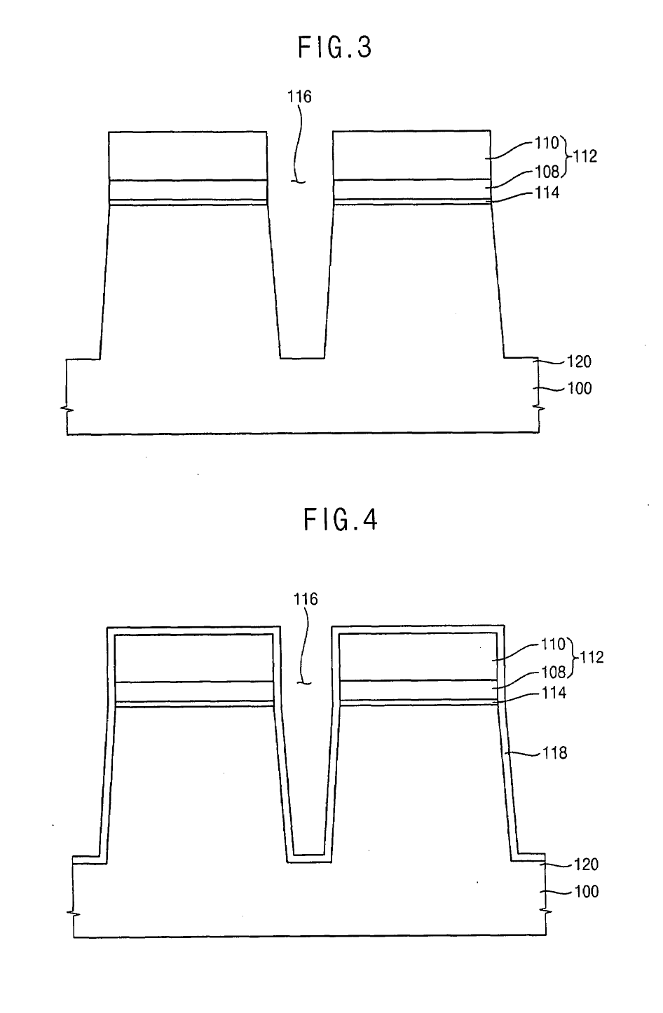

Referring to FIG. 3, the pad oxide layer 102 and the semiconductor substrate 100 may be etched using the mask pattern structure 112 as an etching mask to form a pad oxide layer pattern 114 and a trench 116.

In this example embodiment, the pad oxide layer 102 and the semiconductor substrate 100 may be etched by, e.g., an anisotropic etching process, such as a plasma dry etching process. Further, the trench 116 may reach a depth of about 38,000 Å to about 42,000 Å.

Here, a thickness of the second mask pattern 110 may be reduced while forming the trench 116 using the mask pattern structure 112. For example, given a second mask layer 106 having a thickness of about 10,000 Å to about 14,000 Å, after formation of the trench 116, a second mask pattern 110 may have a thickness of about 7,000 Å. Reducing the thickness of the second mask pattern 110 has an advantage of reducing the aspect ratio of the trench 116.

Referring to FIG. 4, a silicon layer 118 doped with impurities may be formed on an inner face of the trench 116 and the mask pattern structure 112.

In this example embodiment, the impurities may include elements in Group III of the periodic table of the elements. More particularly, boron (B) may be included as an impurity. The thin silicon layer 118 doped with boron may be formed on the inner face of the trench 116 and the mask pattern structure 112. Here, the silicon layer 118 doped with boron, e.g., may include boro-silicate glass (BSG) layer.

The BSG layer may be formed by a thermal diffusion process, a high frequency sputtering process, a CVD process, etc. For example, the BSG layer may be formed by the CVD process under an atmospheric pressure of about 0.2 to about 0.3 using tetra-ethyl-ortho-silicate as a silicon source and tri-ethyl-borate as a boron source.

Here, a thickness of the BSG layer may be adjusted, e.g., by controlling a flow rate of the reaction sources and a reaction time thereof. For example, when the reaction sources may be applied to the semiconductor substrate 100 at a flow rate of about 400 mg/min to about 500 mg/min for about 15 seconds to about 20 seconds, the BSG layer 118 may have a thickness of about 800 Å to about 1,200 Å.

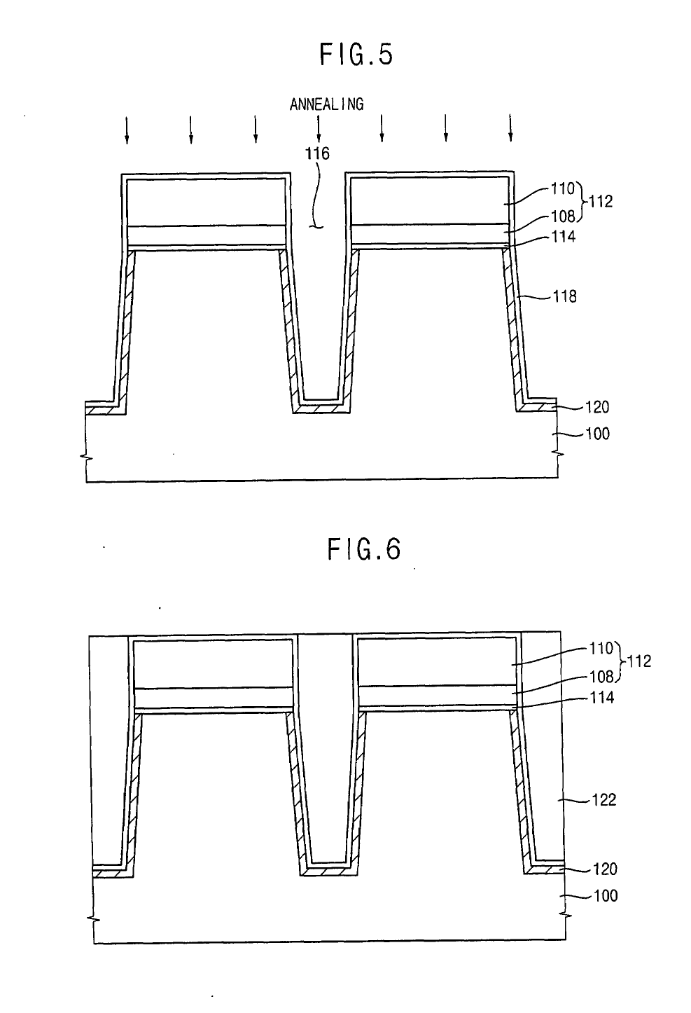

Referring to FIG. 5, the BSG layer 118 may then be thermally treated to form an impurity diffusion region 120 in portions of the semiconductor substrate 100 under the inner face of the trench 116. In this example embodiment, the thermal treatment process may be carried out under, e.g., a nitrogen gas atmosphere, e.g., at a temperature of about 750° C. to about 1,000° C. for about 30 minutes.

Particularly, when the thermal treatment process is performed, the boron in the BSG layer 118 may diffuse into the portions of the semiconductor substrate 100 under the inner face of the trench 116. Thus, the portions of the semiconductor substrate 100 under the inner face of the trench 116 may be doped with the boron to form the impurity diffusion region 120.

The boron in the impurity diffusion region 120 may reduce (if not prevent) electrons on a surface of the isolation pattern or in the isolation pattern from being moved.

Referring to FIG. 6, a sacrificial layer (not shown) may then be formed on the second mask pattern 110 to fill up the trench 116.

In this example embodiment, the sacrificial layer (not shown) may include oxide having a gap-filling characteristic. Examples of the oxide may include undoped silicate glass (USG), boro-phosphor-silicate glass (BPSG), O₃-tetra ethyl ortho silicate undoped silicate glass (O₃-TEOS USG), atomic layer deposition silicon oxide (ALD SiO2), high-density plasma (HDP) oxide, etc.

Alternatively, in FIG. 4, the trench 116 may be completely filled with the BSG layer 118 such that the sacrificial layer (not shown) would not necessarily be formed. In this case, the portions of the semiconductor substrate 100 under the inner face of the trench 116 may be doped with the boron through portions of the BSG layer 118 that makes contact with the inner face of the trench 116. As a result, the process for forming the sacrificial layer may be omitted.

The sacrificial layer may then be removed until an upper face of the second mask pattern 110 is exposed to form a sacrificial layer pattern 122.

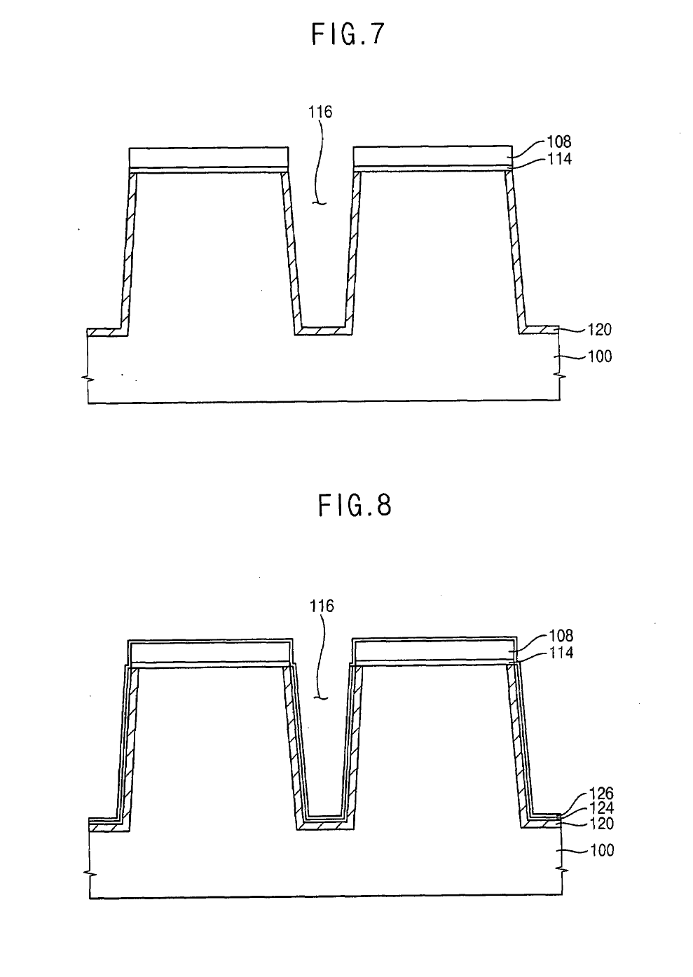

Referring to FIG. 7, the sacrificial layer pattern 122 and the second mask pattern 110 may be removed until an upper face of the first mask pattern 108 is exposed.

Here, as mentioned above, the second mask pattern 110 may have a thickness of about 7,000 Å. Thus, in the circumstance that the trench 116 would be filled with the isolation pattern without removing the second mask pattern 110, a portion of the trench 116, which is to be filled with the isolation layer, may have a high aspect ratio due to the second mask pattern 110 being thick, i.e., having a relatively greater thickness. As a result, a seam or a void may be generated in the isolation layer. The seam or the void may act as a trap site. Therefore, according to this example embodiment, when the second mask pattern 110 is removed to lower the aspect ratio, the seam or the void may not be generated in the isolation pattern.

Here, as described above, since the second mask pattern 110 and the sacrificial layer pattern 122 include oxide, an etching selectivity between the second mask pattern 110 and the sacrificial layer pattern 112 may be low. However, since the first mask pattern 108 includes nitride, an etching selectivity of the first mask pattern 108 with respect to the second mask pattern 110 and the sacrificial layer pattern 122 may be high. Thus, the upper face of the first mask pattern 108 may be used as an etching end point.

The sacrificial layer pattern 122 in the trench 116 as well as the second mask pattern 110 may be substantially completely removed by, e.g., a wet etching process, according to this example embodiment. As a result, the first mask pattern 108, the trench 116 and the impurity diffusion region 120 may be exposed. Removal of the second mask pattern 110 has an advantage of reducing the aspect ratio of the trench 116.

Referring to FIG. 8, the inner face of the trench 116 may be thermally oxidized to form a thin thermal oxide layer 124 on the inner face of the trench 116. Here, the thermal oxidation process may be performed to reduce at least some (if not cure all) damage done to the inner face of the trench 116 caused by a plasma dry etching process for forming the trench 116.

A liner 126 including nitride may then be formed on surfaces of the thermal oxide layer 124, the pad oxide layer pattern 114 and the first mask pattern 108. Here, the liner 126 may reduce stresses in the isolation layer of the trench 116 and also reduce (if not prevent) infiltration of impurities into the isolation layer.

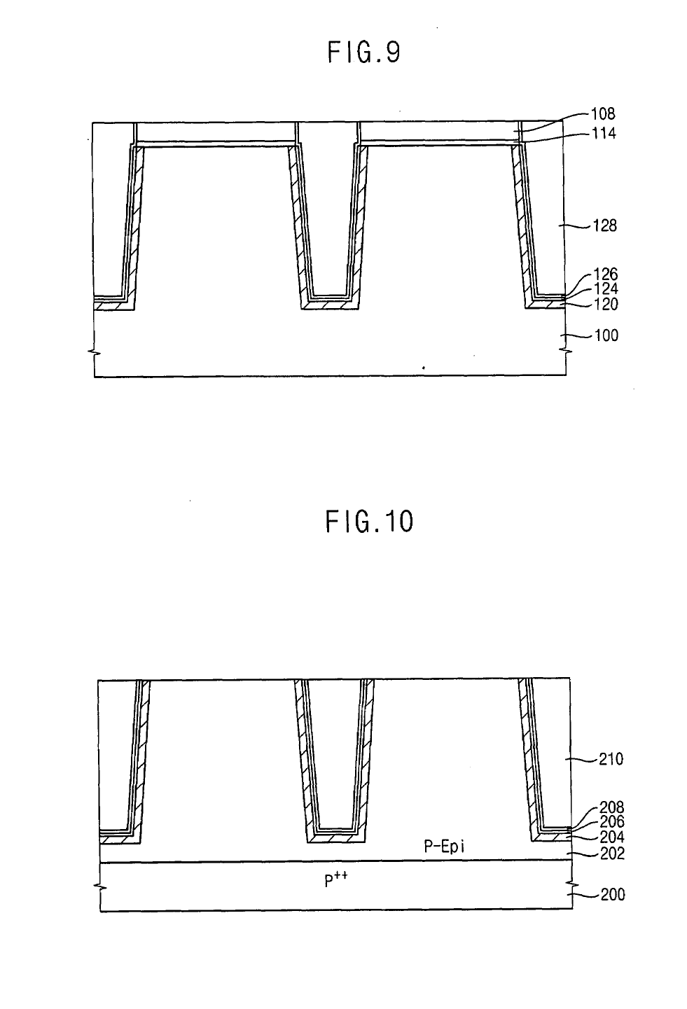

Referring to FIG. 9, an isolation layer (not shown) may be formed on the first mask pattern 108 to fill up the trench 116.

In this example embodiment, the isolation layer may include oxide having a gap-filling characteristic. Examples of the oxide may include undoped silicate glass (USG), boro-phosphor-silicate glass (BPSG), O₃-tetra ethyl ortho silicate undoped silicate glass (O₃-TEOS USG), atomic layer deposition silicon oxide (ALD SiO2), high-density plasma (HDP) oxide, etc.

More particularly as to this example, high-density plasma may be generated using a silane (SiH₄) gas, an oxygen (O₂) gas and an argon (Ar) gas as a plasma source to form a high-density plasma oxide layer. Here, to reduce (if not prevent) a crack or a void from being generated in the trench 116, the trench 116 may be filled with the high-density plasma oxide layer having an enhanced gap-filling characteristic.

Additionally, the isolation layer may be annealed at a temperature of about 800° C. to about 1,050° C. under an inactive gas atmosphere to densify a crystalline structure of the isolation layer, thereby decreasing a wet etching rate of a following cleaning process with respect to the isolation layer.

The isolation layer may be removed until the surface of the first mask pattern 108 is exposed to form an isolation pattern 128.

In this example embodiment, the removal process may include an etch-back process, a chemical mechanical polishing (CMP) process, etc.

Further, after forming the isolation layer 128, the first mask pattern 108 and the pad oxide layer pattern 114 may be additionally removed.

FIGS. 10 to 12 illustrate cross-sectional views of stages in a method of manufacturing an image device using the method depicted via FIGS. 1 to 9 in accordance with another example embodiment of the present invention.

Referring to FIG. 10, a semiconductor substrate 200, e.g., a silicon wafer, is prepared. In this example embodiment, the semiconductor substrate 200 may be, e.g., heavily doped with P-type impurities to form a heavily doped layer P⁺⁺. For example, an epitaxial growth process is then carried out on the semiconductor substrate 200 to form a P-type epitaxial layer 202 lightly doped with P-type impurities,

Processes substantially the same as those illustrated with reference to FIGS. 1 to 9 may then be carried out to form an isolation pattern 201 on the P-type epitaxial layer 202.

Here, since the isolation pattern 210 may be relatively thick, e.g., about 40,000 Å, cross talk may be suppressed. Further, since the impurity diffusion region 204 is formed in a surface of the P-type epitaxial layer 202 making contact with the isolation pattern 210, infiltration into a photodiode region by electrons remaining in the isolation pattern 210 may be reduced (if not prevented). Furthermore, as illustrated with reference to FIGS. 1 to 9, since the isolation layer is formed after partially removing the mask pattern structure, the likelihood of a void and/or a seam occurring in the isolation pattern 210 is reduced (if not prevented). In FIG. 10, non-illustrated reference numerals 206 and 208 refer to a thermal oxide layer and a liner, respectively.

The isolation pattern 210 defines an active pixel region. Unit pixels including one photo diode and four transistors may be formed in the active pixel region.

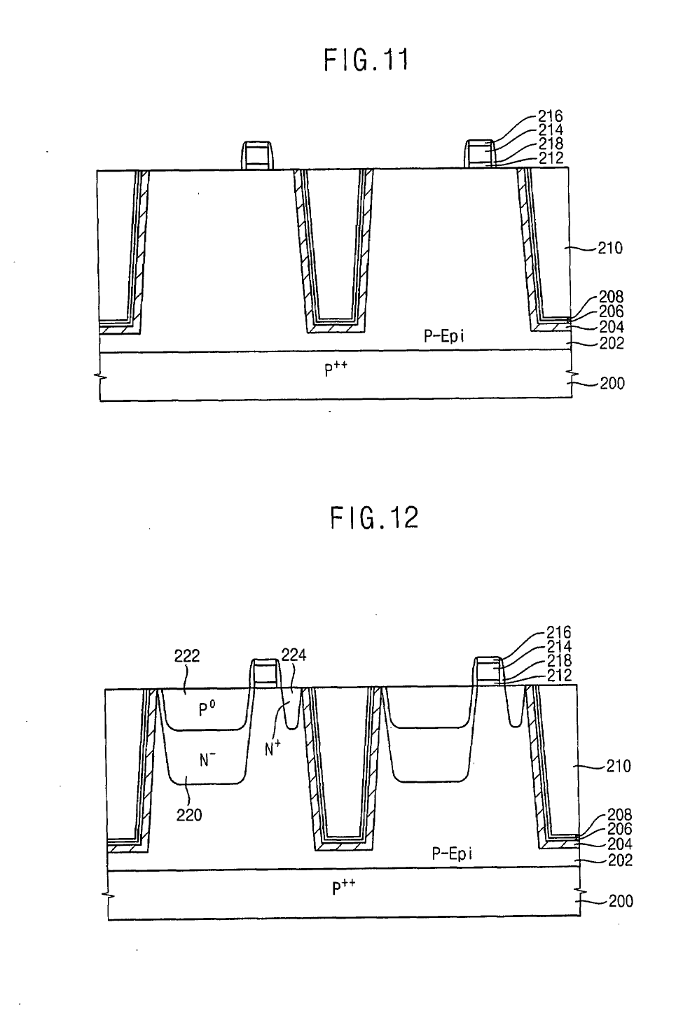

Referring to FIG. 11, a gate insulation layer (not shown), a gate conductive layer (not shown) and a mask layer (not shown) may be sequentially formed on the active pixel region.

In this example embodiment, the gate insulation layer may include oxide. Further, the gate insulation layer may be thin, i.e., may be of relatively small thickness, and may be formed by a thermal oxidation process, a CVD process, etc. The gate conductive layer may include polysilicon doped with impurities, a metal, etc. The mask layer may include nitride.

The mask layer may then be patterned to form mask patterns 216. The gate conductive layer and the gate insulation layer may be etched using the mask patterns 216 as an etching mask to form gate electrodes including gate insulation layer patterns 212, gate conductive layer patterns 214 and mask patterns 216 that are sequentially stacked.

Here, the mask patterns 216 may serve to protect the conductive layer patterns 215 as well as to be used for forming the gate electrodes.

The four gate electrodes may be formed in each of the unit pixels. The four gate electrodes may correspond to a transfer gate electrode, a reset gate electrode, a selection gate electrode and an excess gate electrode, respectively.

Additionally, spacers 218 may be formed on sidewalls of the gate electrodes.

Referring to FIG. 12 (and recalling the example of the substrate 200 being doped as P++), a lightly doped N-type impurity region 220 may be formed at a surface of the P-type epitaxial layer 202 exposed by the gate electrodes and the spacers 218. Here, the lightly doped N-type impurity region 220 may be formed in the P-type epitaxial layer 202, and the lightly doped N-type impurity region 220 may correspond to the photo diode region.

Correspondingly, a P-type impurity region 222 doped with P-type impurities may be formed at a surface of the photo diode region. Here, the P-type impurity region 222 may have a concentration higher than that of the P-type epitaxial layer 202 but lower than that of the heavily doped layer 200. The P-type impurity region 222 may be formed in the lightly doped N-type impurity region 220.

The above-mentioned processes may be carried out to form a photo diode including the lightly doped N-type impurity region 220 and the P-type impurity region 222. In this example embodiment, the photo diode may correspond, e.g., to a low voltage photo diode. Further, the photo diode may be placed in the P-type epitaxial layer 202 at a side of the transfer gate electrode.

Further, a heavily doped N-type impurity region 224 may be formed at another surface of the P-type epitaxial layer 202 exposed by the gate electrodes. In this example embodiment, the heavily doped N-type impurity region 224 may function as source/drain regions of the gate electrodes.

After completing the above-mentioned processes, the transistors including the gate electrode, the spacer 218 and the source/drain regions may be completed. That is, the unit pixels including the photo diode and the four transistors may be formed on the P-type epitaxial layer 202.

A first insulation interlayer (not shown) may be additionally formed on the P-type epitaxial layer 202 to fill up the unit pixels. Further, a metal wiring (not shown) may be formed on the first insulation interlayer. In this example embodiment, the first insulation interlayer may have a multi-layered structure. Further, the metal wiring may be formed in a portion of the first insulation interlayer where the photo diode does not overlapped with the metal wiring. The first insulation interlayer may include a material having a good light transmissivity. In this example embodiment, the first insulation interlayer may include, e.g., silicon oxide. The metal wiring may be electrically connected to the source/drain regions of the unit pixels.

An inner lens (not shown) may be formed on the first insulation interlayer. In this example embodiment, an inner lens layer (not shown) may be formed on the first insulation interlayer. A semi-spherical photoresist pattern (not shown) having a curvature may then be formed on the inner lens layer. The inner lens layer may be etched using the photoresist pattern as an etching mask to form the inner lens having a desired size and curvature.

A second insulation interlayer (not shown) may then be formed on the inner lens. A color filter (not shown), a flat layer (not shown) and a micro lens (not shown) may be sequentially formed on the second insulation interlayer. In this example embodiment, the color filter may create a colored image. Further, the color filter may be formed by forming a photoresist film dyed with a red (R) color, a green (G) color and a blue (B) color on the second insulation interlayer, and by patterning the photoresist film.

The flat layer may then be formed on the color filter. In this example embodiment, the flat layer may be formed by forming a photoresist film on the color filter, and by thermally treating the photoresist film. Additionally, a low temperature oxide layer and a capping layer for protecting the micro lens may be formed on the micro lens.

The image device may be completed by performing the above-mentioned processes. Here, since the isolation pattern may be thick, i.e., may be of relatively larger thickness, the cross talk of the image device may be reduced (if not prevented).

Further, since the impurity diffusion region may be formed in the semiconductor substrate under the inner face of the trench, the likelihood of infiltration into the photo diode of electrons may be reduced (if not avoided). As a result, a white spot may not be generated, and a dark level may also be decreased.

Furthermore, since the isolation pattern may be formed in the trench after partially removing the mask pattern structure, the void and/or the seam may not be generated in the isolation pattern.

According to one or more embodiments of the present invention, the isolation pattern may be relatively thicker, hence the cross talk of the image device may be reduced (if not prevented). Further, since the inner face of the trench may be doped with the impurities, the likelihood of generating the white spot and/or the dark level may also be decreased.

An image device (according to one or more embodiments of the present invention) including the isolation pattern may have an improved reliability.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming an isolation layer, the method comprising:
forming mask pattern structure on a substrate to partially expose the substrate;
etching the substrate using the mask pattern as an etching mask to form a trench;
forming an impurity diffusion region at an inner face of the trench; and
filling the trench with the isolation layer.

2. The method as claimed in claim 1, wherein forming the impurity diffusion region comprises:
forming a silicon layer doped with one or more impurities on the inner face of the trench; and
thermally treating the silicon layer doped with the impurities to form the impurity diffusion region.

3. The method as claimed in claim 2, wherein thermally treating the silicon layer is carried out under a nitrogen gas atmosphere.

4. The method as claimed in claim 2, wherein the one or more impurities include elements in Group III of the periodic table of the elements.

5. The method as claimed in claim 4, wherein the silicon layer doped with the impurities comprises boro-silicate glass (BSG), and the silicon layer doped with the impurities are formed by a chemical vapor deposition (CVD) process or a thermal diffusion process.

6. The method as claimed in claim 1, wherein the forming the mask pattern structure includes:
forming a first mask layer on the substrate;
forming a second mask layer on the first mask layer, the second mask layer having an etching selectivity different from that of the first mask layer;
forming a second mask pattern from the second mask layer;
forming a first mask pattern from the first mask layer corresponding to the second mask pattern; and
at least partially removing the second mask pattern before filling the trench with the isolation pattern.

7. The method as claimed in claim 6, wherein removing the second mask pattern comprises:
forming a sacrificial layer on the second mask pattern to fill up the trench having the impurity diffusion region;
performing a planarization process until the first mask pattern is exposed to remove the second mask pattern and a first portion of the sacrificial layer; and
removing a remaining second portion of the sacrificial layer.

8. The method as claimed in claim 7, wherein the sacrificial layer includes one or more of boro-silicate glass (BSG), phosphor-silicate glass (PSG), undoped silicate glass (USG), boro-phosphor-silicate glass (BPSG) and atomic layer deposition (ALD) silicon oxide.

9. The method as claimed in claim 6, wherein the first mask pattern includes nitride, and the second mask pattern includes oxide.

10. The method as claimed in claim 1, after forming the impurity diffusion region, the method further comprising:
thermally oxidizing the inner face of the trench to reduce at least some damage thereof; and
forming a nitride liner on the oxidized inner face of the trench.

11. The method as claimed in claim 1, wherein the substrate is a first substrate, and the method further comprises:
providing a semiconductor second substrate; and
forming a pad oxide on the second substrate;
wherein the pad oxide layer and the second substrate represent the first substrate.

12. A method of manufacturing an image device, the method comprising:
forming mask pattern structure on a substrate to partially expose the substrate;
etching the substrate using the mask pattern as an etching mask to form a trench;
forming an impurity diffusion region at an inner face of the trench;
filling the trench with an isolation layer; and
forming unit pixels including a photo diode and transistors on an active region defined by the isolation layer.

13. The method as claimed in claim 12, wherein forming the impurity diffusion region comprises:
forming a silicon layer doped with impurities on the inner face of the trench; and
thermally treating the silicon layer doped with the impurities to form the impurity diffusion region.

14. The method as claimed in claim 13, wherein thermally treating the silicon layer is carried out under a nitrogen gas atmosphere.

15. The method as claimed in claim 13, wherein the one or more impurities include elements in Group III of the periodic table of the elements.

16. The method as claimed in claim 15, wherein the silicon layer doped with the impurities comprises boro-silicate glass (BSG), and is formed by a chemical vapor deposition (CVD) process or a thermal diffusion process.

17. The method as claimed in claim 12, wherein the step of forming the mask pattern structure includes:
forming a first mask layer on the substrate;
forming a second mask layer on the first mask layer, the second mask layer having an etching selectivity different from that of the first mask layer;
forming a second mask pattern from the second mask layer;
forming a first mask pattern from the first mask layer corresponding to the second mask pattern; and
at least partially removing the second mask pattern before filling the trench with the isolation pattern.

18. The method as claimed in claim 17, wherein removing the second mask pattern comprises:
forming a sacrificial layer on the second mask pattern to fill up the trench having the impurity diffusion region;
performing a planarization process until the first mask pattern is exposed to remove the second mask pattern and a first portion of the sacrificial layer; and
removing a remaining second portion of the sacrificial layer.

19. The method as claimed in claim 18, wherein the sacrificial layer includes one or more of boro-silicate glass (BSG), phosphor-silicate glass (PSG), undoped silicate glass (USG), boro-phosphor-silicate glass (BPSG) and atomic layer deposition (ALD) silicon oxide.

20. The method as claimed in claim 17, wherein the mask pattern includes nitride, and the second mask pattern includes oxide.

21. The method as claimed in claim 12, after forming the impurity diffusion region, the method further comprising:
thermally oxidizing the inner face of the trench to reduce at least some damage thereof; and
forming a nitride liner on the oxidized inner face of the trench.

22. The method as claimed in claim 12, wherein the substrate is a first substrate, and the method further comprises:
providing a semiconductor second substrate; and
forming a pad oxide on the second substrate;
wherein the pad oxide layer and the second substrate represent the first substrate.
